(19) United States
(12) Patent Application Publication
(10) Pub. No.: US 2015/0021708 A1
(43) Pub. Date: Jan. 22, 2015

(54) PIXEL STRUCTURE

(71) Applicant: Au Optronics Corporation, Hsinchu (TW)

(72) Inventors: Sung-Hui Lin, New Taipei City (TW); Hsiao-Wei Cheng, Hsinchu County (TW); Ming-Yung Huang, Changhua County (TW); Pin-Miao Liu, Hsinchu County (TW)

(21) Appl. No.: 14/509,061

(22) Filed: Oct. 8, 2014

Related U.S. Application Data
(63) Continuation of application No. 12/975,356, filed on Dec. 22, 2010.

(30) Foreign Application Priority Data
Aug. 31, 2010 (TW) 99129268

(51) Int. Cl. H01L 27/12

(52) U.S. Cl. CPC H01L 27/124
USPC 257/390

(57) ABSTRACT

A pixel structure includes a substrate, a scan line on the substrate, a data line set, an active device, and a pixel electrode. The substrate has a display region and a peripheral region around the display region. The display region includes at least one sub-pixel region. The data line set is disposed on the substrate, located at one side of the sub-pixel region, and intersected with the scan line to form at least one first intersecting region. The data line set includes a first and a second data lines that are intersected to form at least one second intersecting region. The first and the second data lines are electrically insulated. The active device electrically connects the scan line and to the first data line or the second data line in the data line set. The pixel electrode is located in the sub-pixel region and electrically connects the active device.

### CROSS-REFERENCE TO RELATED APPLICATION

This is a continuation application of patent application Ser. No. 12/975,356, filed on Dec. 22, 2010, which claims the priority benefit of Taiwan application serial no. 99129268, filed on Aug. 31, 2010. The entirety of each of the above-mentioned patent applications is hereby incorporated by reference herein and made a part of this specification.

### BACKGROUND OF THE INVENTION

1. Field of the Invention

The invention relates to a pixel structure. More particularly, the invention relates to a pixel structure capable of resolving a vertical cross-talk issue arising in a liquid crystal display (LCD).

2. Description of Related Art

In general, a pixel structure of an LCD includes a scan line, a data line, an active device, and a pixel electrode. In the pixel structure, the greater the area of the pixel electrode, the higher the aperture ratio of the LCD. However, when the pixel electrode and the data line are overly close, stray capacitance (Cpd) between the pixel electrode and the data line increases. As a result, when a switch device is in an off state, the voltage of the pixel electrode is affected by signals transmitted through the data line, and the cross-talk effect is generated, which poses a negative impact on the display quality of the LCD.

On the other hand, existing large-size LCDs are mostly driven in a column-inversion manner. Theoretically, the coupling capacitance between the pixel electrode and the signal lines (the data lines) located at respective sides of the pixel electrode is the same, such that the value of vertical cross-talk is zero. Here, only one data line is located at each of the two sides of the pixel electrode, and each data line is perfectly straight and is not intersected with each other. Nonetheless, multiple photo mask processes performed on the pixel structure result in misalignment to a certain extent, and thus a positional shift exists among each film layer of the pixel structure. Consequently, the distance between each pixel electrode and each signal line located at each of the two sides of the pixel electrode is different, and the coupling capacitance between each pixel and each signal line located at each side of the pixel electrode is different as well. Namely, the vertical cross-talk issue remains unresolved, thus affecting the display quality of the LCD.

### SUMMARY OF THE INVENTION

The invention is directed to a pixel structure capable of resolving an issue of vertical cross-talk in an LCD.

The invention provides a pixel structure that includes a substrate, a scan line, a data line set, an active device, and a pixel electrode. The substrate has a display region and a peripheral region. The display region includes at least one sub-pixel region. The scan line is disposed on the substrate. The data line set is disposed on the substrate, located at one side of the sub-pixel region, and intersected with the scan line to form at least one first intersecting region. The data line set includes a first data line and a second data line that are intersected to form at least one second intersecting region. The first and the second data lines are electrically insulated. The active device is electrically connected to the scan line and electrically connected to the first data line or the second data line in the data line set. The pixel electrode is disposed in the sub-pixel region and electrically connected to the active device.

The invention further provides a pixel structure that includes a substrate, a scan line, a first data line set, a second data line set, a first active device, a second active device, a first pixel electrode, and a second pixel electrode. The substrate has a display region and a peripheral region. Here, the display region includes at least one pixel region which has a first sub-pixel region and a second sub-pixel region. The scan line is disposed on the substrate. The first data line set is disposed on the substrate, located at one side of the pixel region, and intersected with the scan line to form at least one first intersecting region. Here, the first data line set includes a first data line and a second data line that are intersected to form at least one second intersecting region. The first data line is electrically insulated from the second data line. The second data line set is disposed on the substrate, located at the other side of the pixel region, and intersected with the scan line to form at least one third intersecting region. Here, the second data line set includes a third data line and a fourth data line that are intersected to form at least one fourth intersecting region. The third data line is electrically insulated from the fourth data line. The first active device is electrically connected to the scan line and electrically connected to the first data line or the second data line in the first data line set. The first pixel electrode is disposed in the first sub-pixel region and electrically connected to the first active device. The second active device is electrically connected to the scan line and electrically connected to the third data line or the fourth data line in the second data line set. The second pixel electrode is disposed in the second sub-pixel region and electrically connected to the second active device.

Based on the above, the data line set is located at one side of the sub-pixel region in this invention. The data line set includes the first data line and the second data line that are intersected to form at least one intersecting region. When the first data line and the second data line are provided with signals having different polarity, the data lines having two different polarity are located at only one side of the pixel electrode. Therefore, even though the distance between each pixel electrode and the data lines located at respective sides of the pixel electrodes is different because of process variation, the coupling capacitance between the pixel electrode and the data lines located at the same side of the pixel electrode can be compensated, and thereby the vertical cross-talk phenomenon can be mitigated.

In order to make the aforementioned and other features and advantages of the disclosure comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view illustrating a display panel according to an embodiment of the invention.

FIG. 2A is a schematic top view partially illustrating a pixel array according to an embodiment of the invention.

FIG. 2B is a schematic cross-sectional view taken along sectional lines A-A′ and B-B′ in FIG. 2A.

FIG. 3 to FIG. 10 are schematic top views partially illustrating a pixel array according to several embodiments of the invention.

### DESCRIPTION OF EMBODIMENTS

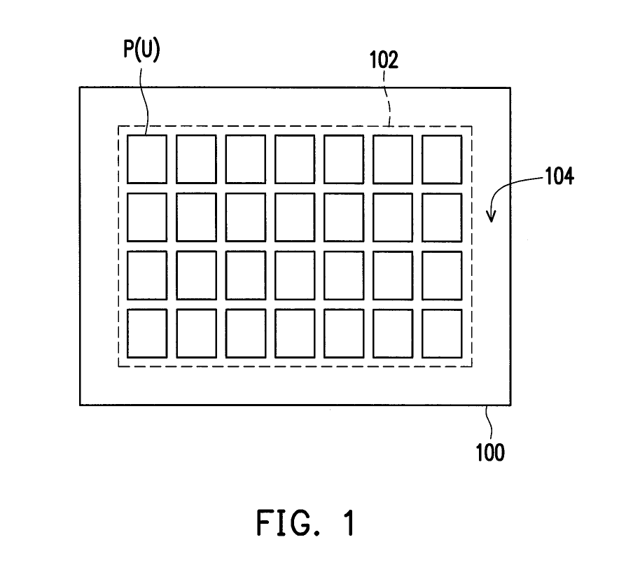

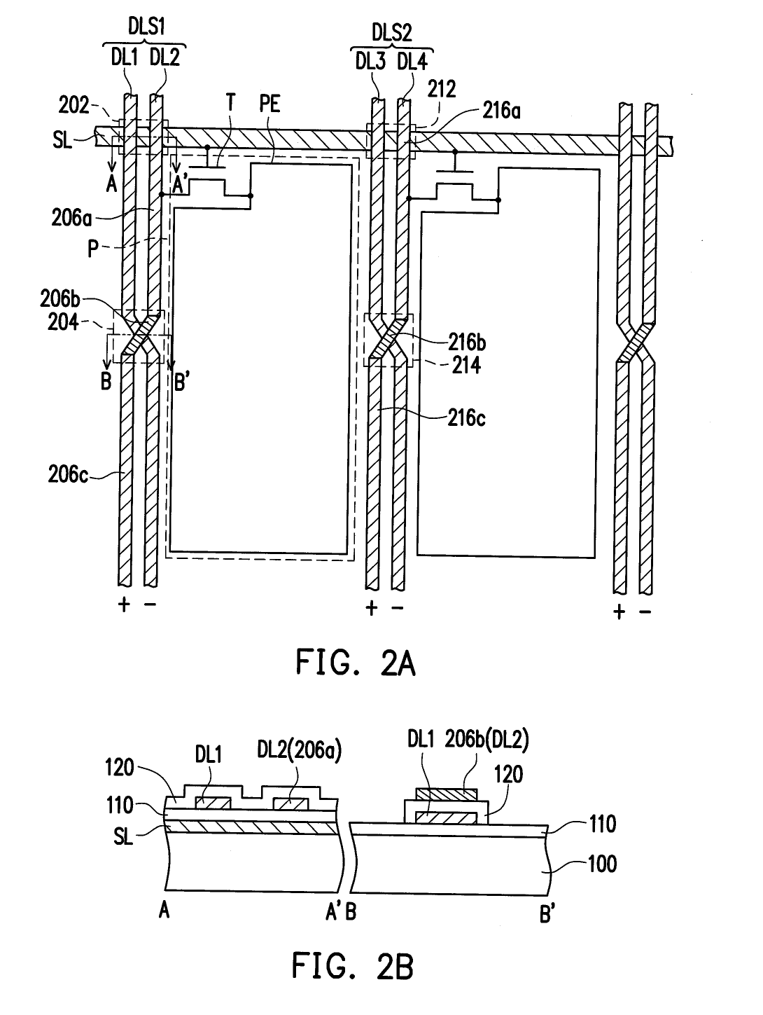

FIG. 1 is a schematic top view illustrating a display panel according to an embodiment of the invention. FIG. 2A is a schematic top view partially illustrating a pixel array according to an embodiment of the invention. FIG. 2B is a schematic cross-sectional view taken along sectional lines A-A′ and B-B′ in FIG. 2A. With reference to FIG. 1, FIG. 2A, and FIG. 2B, the pixel array is comprised of a plurality of pixel structures arranged in array, and each of the pixel structures includes a substrate 100, a scan line SL, a data line set DLS1, an active device T, and a pixel electrode PE.

To be more specific, the substrate 100 has a display region 102 and a peripheral region 104. The display region 102 includes at least one sub-pixel region P. Each sub-pixel region P in the display region 102 of the substrate 100 correspondingly has one pixel structure. Namely, the pixel structures respectively located in the sub-pixel regions P together form the pixel array of the display panel. The substrate 100 can be made of glass, quartz, organic polymer, a non-light-transmissive/reflective material (such as a conductive material, metal, wafer, ceramics, or other appropriate materials), or other appropriate materials. When the substrate 100 is made of the conductive material or metal, the substrate 100 is covered by an insulating layer (not shown) to prevent short circuit.

The scan line SL is disposed on the substrate 100. The data line set DLS1 is disposed on the substrate 100 and located at one side of the sub-pixel region P. In this embodiment, the scan line SL and the data line set DLS1 are intersected with each other. In other words, an extending direction of the data line set DLS1 is not parallel to an extending direction of the scan line SL. Preferably, the extending direction of the data line set DLS1 is substantially perpendicular to the extending direction of the scan line SL. Besides, an insulating layer 110 is sandwiched between the scan line SL and the data line set DLS1, so as to electrically insulate the scan line SL from the data line set DLS1. The data line set DLS1 is further covered by another insulating layer 120. In consideration of electrical conductivity, the scan line SL and the data line set DLS1 are normally made of metallic materials. However, the invention is not limited thereto. According to other embodiments of the invention, the scan line SL and the data line set DLS1 can be made of other conductive materials (such as an alloy, a metal nitride material, a metal oxide material, a metal oxynitride material, or other suitable materials), or a stacked layer containing the metallic material and any other conductive material.

The intersection between the data line set DLS1 and the scan line SL is the first intersecting region 202. The data line set DLS1 includes a first data line DL1 and a second data line DL2 that are intersected with each other to form at least one second intersecting region 204. The first data line DL1 is electrically insulated from the second data line DL2.

As described in the embodiment shown in FIG. 2A, the first data line DL1 is a complete signal line, and the second data line DL2 includes a plurality of line segments 206a, 206b, and 206c. Specifically, the level of the line segment 206b of the second data line DL2 located in the second intersecting region 204 is different from the level of the first data line DL1 located in the second intersecting region 204. In this embodiment, the first data line DL1 and the line segments 206a and 206c of the second data line DL2 are in the same film layer. The line segment 206b of the second data line DL2 is located above the first data line DL1 and crosses over the first data line DL1. Here, the line segment 206b can be made of a metallic material or any other conductive material (such as an alloy, a metal nitride material, a metal oxide material, a metal oxynitride material, or any other suitable material), or a stacked layer containing the metallic material and any other conductive material. The insulating layer 120 is sandwiched between the line segment 206b of the second data line DL2 and the first data line DL1, such that the first data line DL1 is electrically insulated from the second data line DL2. The line segments 206a, 206b, and 206c of the second data line DL2 can be electrically connected to one another directly or through contact windows (not shown) formed in the insulating layer 120.

The active device T is electrically connected to the scan line SL and electrically connected to the first data line DL1 or the second data line DL2 in the data line set DLS1. In this embodiment, the active device T is electrically connected to the second data line DL2, for instance. The active device T is, for example, a bottom-gate thin film transistor (TFT) or a top-gate TFT, and the active device T includes a gate, a source, and a drain. The gate of the active device T is electrically connected to the scan line SL, and the source is electrically connected to the second data line DL2. A semiconductor material of the bottom-gate TFT or the top-gate TFT has a single-layer structure or a multi-layer structure, and the semiconductor material can be amorphous silicon, polysilicon, micro-silicon, mono-silicon, an organic semiconductor material, an oxide semiconductor material (e.g., indium zinc oxide, indium germanium zinc oxide, any other suitable material, or a combination of the above), any other suitable material, the aforesaid material having dopant, or a combination of the above, for instance.

The pixel electrode PE is disposed in the sub-pixel region P and electrically connected to the active device T. The pixel electrode PE can be a transparent pixel electrode, a reflective pixel electrode, or a transflective pixel electrode. A material of the transparent pixel electrode includes metal oxide, such as indium tin oxide, indium zinc oxide, aluminum tin oxide, aluminum zinc oxide, indium germanium zinc oxide, other suitable oxide, or a stacked layer having at least two of the above materials. A material of the reflective pixel electrode includes a metallic material having high reflectivity. According to an embodiment of the invention, the pixel electrode PE is formed above the insulating layer 120 and electrically connected to the drain of the active device T through a contact window (not shown) formed in the insulating layer 120.

In this embodiment, the first data line DL1 and the second data line DL2 have different polarity. In detail, when the aforesaid pixel structure is operated or driven, signals on the first data line DL1 and on the second data line DL2 respectively have the negative polarity (−) and the positive polarity (+) within the same time period. Alternatively, the signals on the first data line DL1 and on the second data line DL2 respectively have the positive polarity (+) and the negative polarity (−) within the same time period. The polarity of the first data line DL1 and the polarity of the second data line DL2 are relative to the common voltage (Vcom) in the display panel.

In this embodiment, the first and the second data lines DL1 and DL2 in the data line set DLS1 of the pixel structure are intersected with each other to form at least one second intersecting region 204, and the first and the second data lines DL1 and DL2 have different polarity. Namely, the data lines with two different polarity can be located at only one side of the pixel structure of this embodiment. Therefore, even though the distance between each pixel electrode PE and the data lines located at respective sides of the pixel electrode PE is different because of process variation, the coupling capacitance between the pixel electrode PE and the data line set DLS1 (the first and the second data lines DL1 and DL2 located at the same side of the pixel electrode PE) can be compensated, and thereby the vertical cross-talk phenomenon can be mitigated.

As shown in FIG. 2A, another data line set DLS2 is further disposed at the other side of the sub-pixel region P according to another embodiment of the invention. The intersection between the data line set DLS2 and the scan line SL is the third intersecting region 212. The data line set DLS2 includes a third data line DL3 and a fourth data line DL4 that are intersected with each other to form at least one fourth intersecting region 214. The third data line DL3 is electrically insulated from the fourth data line DL4.

Similarly, as described in the embodiment shown in FIG. 2A, the third data line DL3 is a complete signal line, and the fourth data line DL4 includes a plurality of line segments 216a, 216b, and 216c. Specifically, the level of the line segment 216b of the fourth data line DL4 located in the fourth intersecting region 214 is different from the level of the third data line DL3 located in the fourth intersecting region 214. In this embodiment, the third data line DL3 and the line segments 216a and 216c of the fourth data line DL4 are in the same film layer. The line segment 216b of the fourth data line DL4 is located above the third data line DL3 and crosses over the third data line DL3. The insulating layer 120 is also sandwiched between the third data line DL3 and the line segment 216b of the fourth data line DL4, such that the third data line DL3 is electrically insulated from the fourth data line DL4 The line segments 216a, 216b, and 216c of the fourth data line DL4 can be electrically connected to one another directly or through contact windows (not shown) formed in the insulating layer 120.

In this embodiment, the third data line DL3 and the fourth data line DL4 have different polarity. In detail, when the aforesaid pixel structure is operated or driven, signals on the third data line DL3 and on the fourth data line DL4 respectively have the negative polarity (−) and the positive polarity (+) within the same time period. Alternatively, the signals on the third data line DL3 and on the fourth data line DL4 respectively have the positive polarity (+) and the negative polarity (−) within the same time period. The polarity of the third data line DL3 and the polarity of the fourth data line DL4 are relative to the common voltage (Vcom) in the display panel.

Based on the above, in the pixel structure depicted in FIG. 2A, the data line set DLS1 (the first and the second data lines DL1 and DL2) is located at one side of the pixel electrode PE, and the data line set DLS2 (the third and the fourth data lines DL3 and DL4) is located at the other side of the pixel electrode PE. The first and the second data lines DL1 and DL2 have different polarity, and the third and the fourth data lines DL3 and DL4 have different polarity. Hence, even though the distance between the pixel electrode PE and the data line sets DLS1 and DLS2 located at respective sides of the pixel electrode PE is different because of process variation, the coupling capacitance between the pixel electrode PE and the data line sets DLS1 (the first and the second data lines DL1 and DL2) and DLS2 (the third and the fourth data lines DL3 and DL4) located at respective sides of the pixel electrode PE can be compensated, and thereby the vertical cross-talk phenomenon can be mitigated.

In the embodiment depicted in FIG. 2A, note that the line segment 206b of the second data line DL2 is located above the first data line DL1 and crosses over the first data line DL1, and the line segment 216b of the fourth data line DL4 is located above the third data line DL3 and crosses over the third data line DL3. However, the invention is not limited thereto. According to other embodiments of the invention, the line segment 206b of the second data line DL2 can also be located below the first data line DL1 and across the first data line DL1, and the line segment 216b of the fourth data line DL4 can be located below the third data line DL3 and across the third data line DL3.

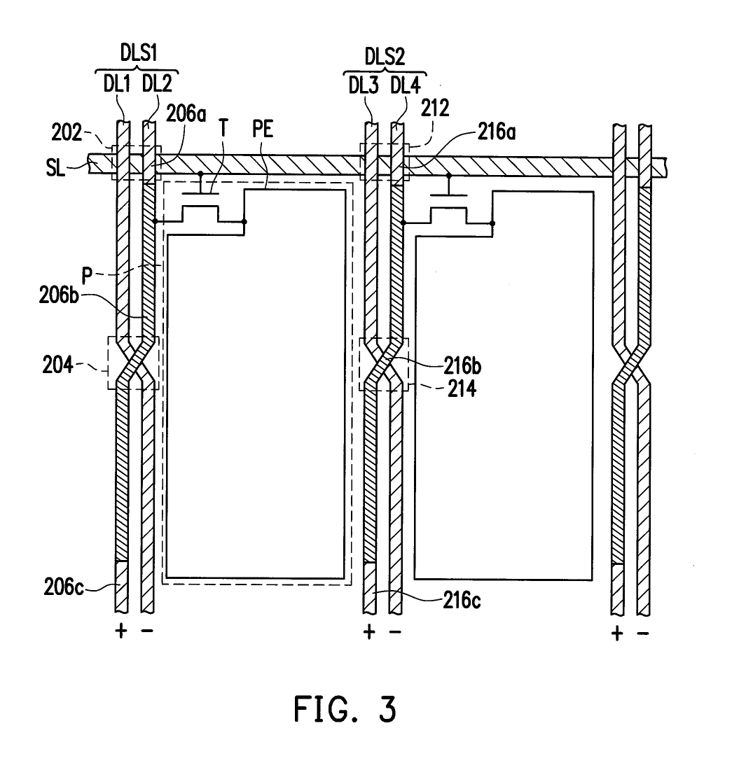

FIG. 3 is a schematic top view partially illustrating a pixel array according to an embodiment of the invention. The embodiment shown in FIG. 3 is similar to the embodiment shown in FIG. 2A, and thus components identical to those in FIG. 2A are represented by the same numerals in FIG. 3 and are not repeated herein. The difference between the embodiment shown in FIG. 3 and the embodiment shown in FIG. 2A lies in that the line segment 206b of the second data line DL2 is not only located in the intersecting region 204 but also extended outside the intersecting region 204. Similarly, the line segment 216b of the fourth data line DL4 is not only located in the intersecting region 214 but also extended outside the intersecting region 214. That is to say, in the embodiment shown in FIG. 3, the first data line DL1 and the line segments 206a and 206c of the second data line DL2 are in the same film layer/at the same level, while the line segment 206b of the second data line DL2 is in a different film layer/at a different level. For instance, the line segment 206b of the second data line DL2 can be in a film layer above or below the film layer where the line segments 206a and 206c and the first data line DL1 are located. The third data line DL3 and the line segments 216a and 216c of the fourth data line DL4 are in the same film layer/at the same level, while the line segment 216b of the fourth data line DL4 is in a different film layer/at a different level. For instance, the line segment 216b of the fourth data line DL4 can be in a film layer above or below the film layer where the line segments 216a and 216c and the third data line DL3 are located.

In the embodiments shown in FIG. 2A and FIG. 3, each of the data line sets DLS1 and DLS2 has only one intersecting region therein. However, the invention is not limited thereto. According to other embodiments of the invention, each of the data line sets DLS1 and DLS2 can have a plurality of intersecting regions therein, which is elaborated hereinafter.

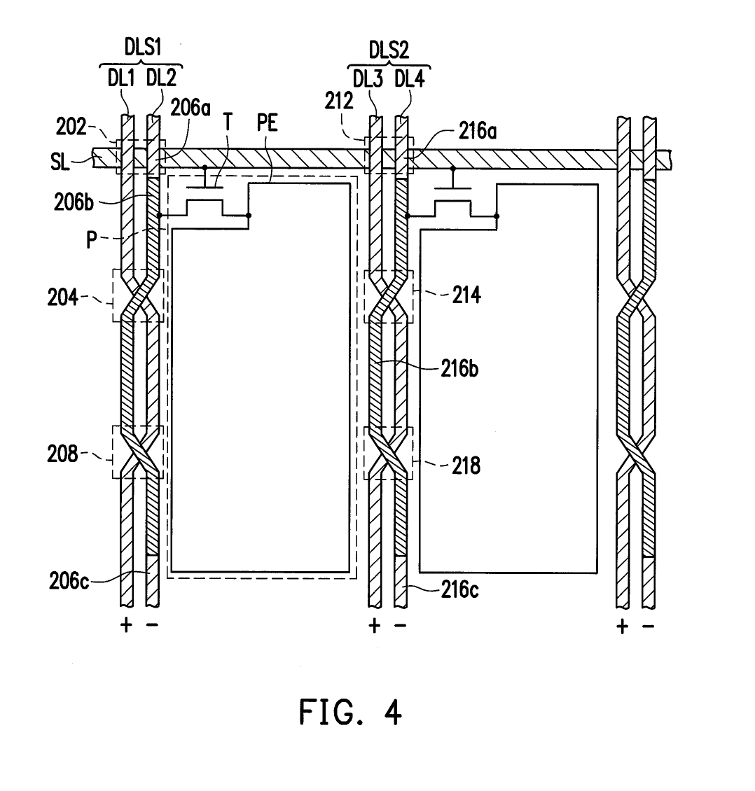

FIG. 4 is a schematic top view partially illustrating a pixel array according to an embodiment of the invention. The embodiment shown in FIG. 4 is similar to the embodiment shown in FIG. 3, and thus components identical to those in FIG. 3 are represented by the same numerals in FIG. 4 and are not repeated herein. The difference between the embodiment shown in FIG. 4 and the embodiment shown in FIG. 3 rests in that there are two intersecting regions 204 and 208 between the first and the second data lines DL1 and DL2, and there are two intersecting regions 214 and 218 between the third and the fourth data lines DL3 and DL4.

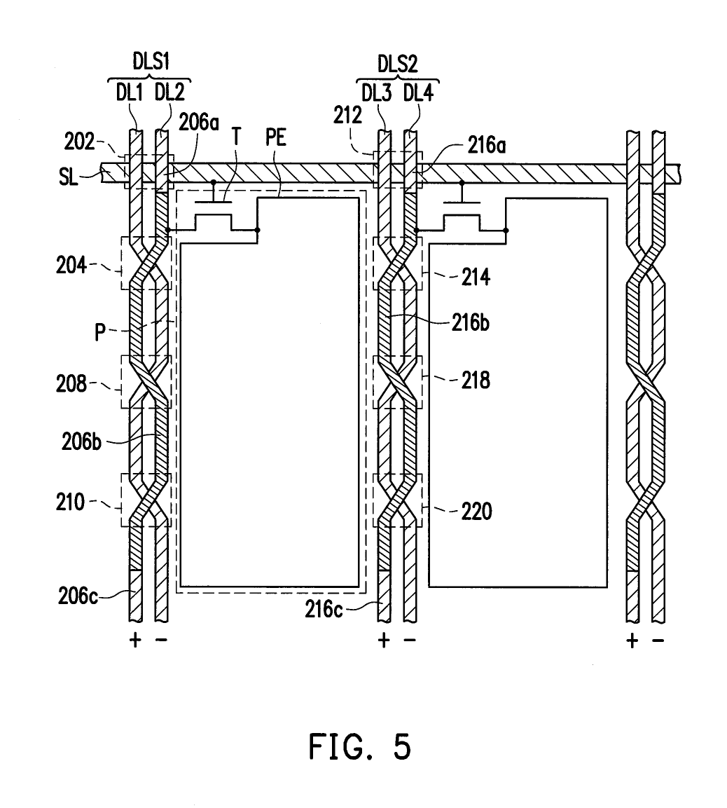

FIG. 5 is a schematic top view partially illustrating a pixel array according to an embodiment of the invention. The embodiment shown in FIG. 5 is similar to the embodiment shown in FIG. 3, and thus components identical to those in FIG. 3 are represented by the same numerals in FIG. 5 and are not repeated herein. The difference between the embodiment shown in FIG. 5 and the embodiment shown in FIG. 3 rests in that there are intersecting regions 204, 208, and 210 between the first and the second data lines DL1 and DL2, and there are intersecting regions 214, 218, and 220 between the third and the fourth data lines DL3 and DL4.

In the embodiments depicted in FIG. 2A to FIG. 5, one of the data lines in each data line set is a complete signal line, while the other data line is comprised of a plurality of line segments. However, the invention is not limited thereto. According to another embodiment of the invention, both of the data lines in each data line set are comprised of a plurality of line segments, which is elaborated hereinafter.

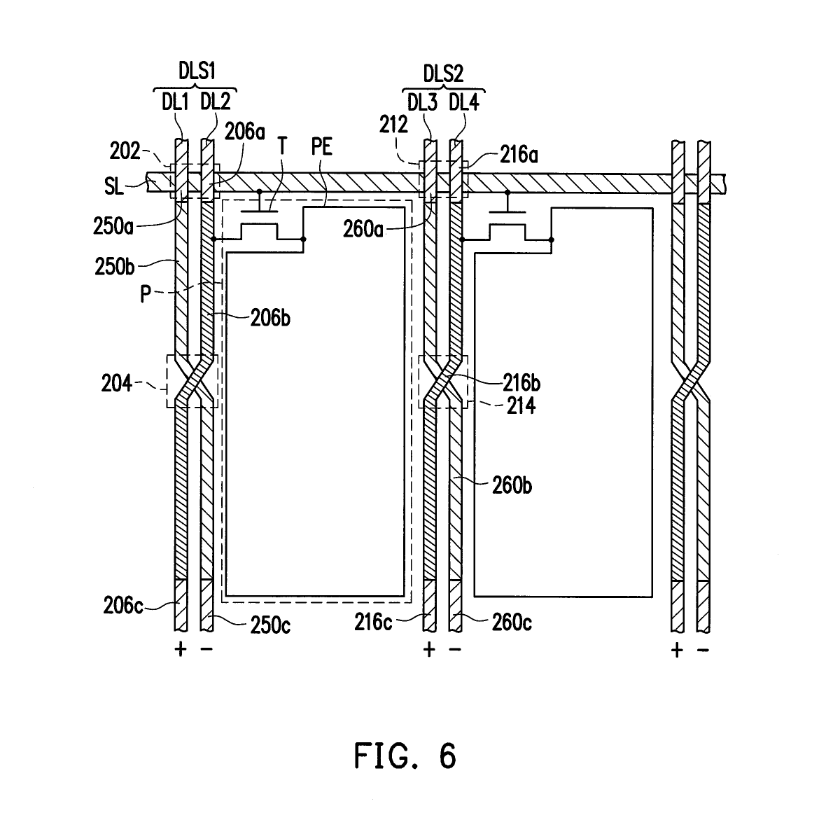

FIG. 6 is a schematic top view partially illustrating a pixel array according to an embodiment of the invention. The embodiment shown in FIG. 6 is similar to the embodiment shown in FIG. 3, and thus components identical to those in FIG. 3 are represented by the same numerals in FIG. 6 and are not repeated herein. The difference between the embodiment shown in FIG. 6 and the embodiment shown in FIG. 3 lies in that the first data line DL1 includes a plurality of line segments 250a, 250b, and 250c, and the second data line DL2 includes a plurality of line segments 206a, 206b, and 206c. The level of the line segment 206b of the second data line DL2 located in the intersecting region 204 is different from the level of the line segment 250b of the first data line DL1 located in the intersecting region 204. Specifically, the line segments 250a and 250c of the first data line DL1 and the line segments 206a and 206c of the second data line DL2 are in the same film layer/at the same level. The line segment 206b of the second data line DL2 is located above the line segment 250b of the first data line DL1 and crosses over the line segment 250b of the first data line DL1. Certainly, in other embodiments of the invention, the line segment 206b of the second data line DL2 can be located below the line segment 250b of the first data line DL1 and across the line segment 250b of the first data line DL1. Similarly, the line segments 250a, 250b, and 250c of the first data line DL1 can be electrically connected to one another directly or through contact windows. The line segments 206a, 206b, and 206c of the second data line DL2 can be electrically connected to one another directly or through contact windows.

In the embodiment shown in FIG. 6, the third data line DL3 includes a plurality of line segments 260a, 260b, and 260c, and the fourth data line DL4 includes a plurality of line segments 216a, 216b, and 216c. The level of the line segment 216b of the fourth data line DL4 located in the intersecting region 214 is different from the level of the line segment 260b of the third data line DL3 located in the intersecting region 214. Specifically, the line segments 260a and 260c of the third data line DL3 and the line segments 216a and 216c of the fourth data line DL4 are in the same film layer/at the same level. The line segment 216b of the fourth data line DL4 is located above the line segment 260b of the third data line DL3 and crosses over the line segment 260b of the third data line DL3. Certainly, in other embodiments of the invention, the line segment 216b of the fourth data line DL4 can be located below the line segment 260b of the third data line DL3 and across the line segment 260b of the third data line DL3. Similarly, the line segments 260a, 260b, and 260c of the third data line DL3 can be electrically connected to one another directly or through contact windows. The line segments 216a, 216b, and 216c of the fourth data line DL4 can be electrically connected to one another directly or through contact windows.

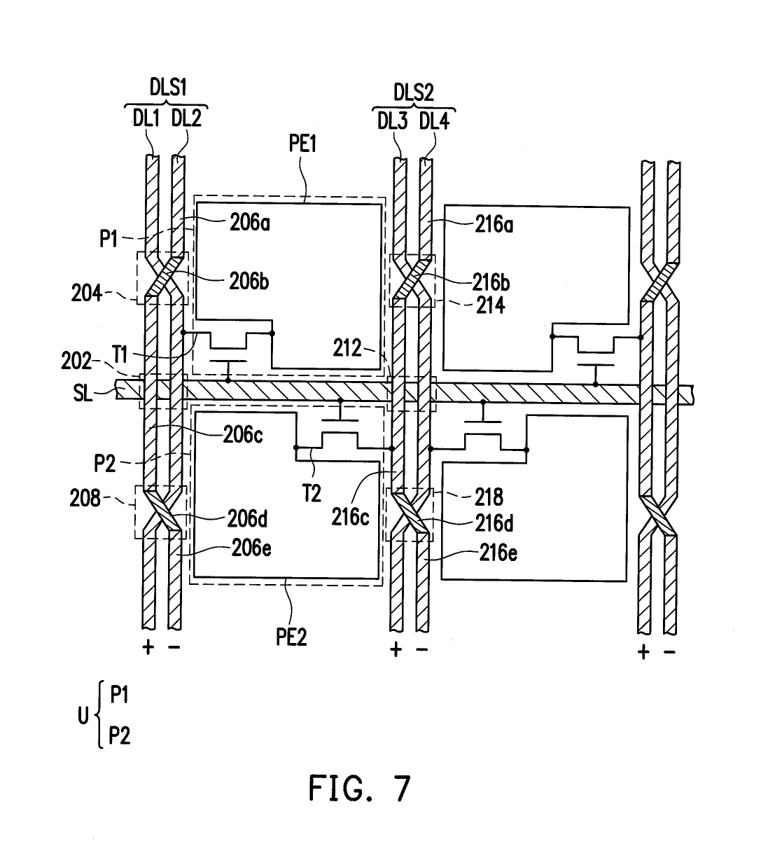

FIG. 7 is a schematic top view partially illustrating a pixel array according to an embodiment of the invention. The embodiment shown in FIG. 7 is similar to the embodiment shown in FIG. 2A, and thus components identical to those in FIG. 2A are represented by the same numerals in FIG. 7 and are not repeated herein.

With reference to FIG. 7 and FIG. 1, the pixel structure of this embodiment includes a substrate 100, a scan line SL, a first data line set DLS1, a second data line set DLS2, a first active device T1, a second active device T2, a first pixel electrode PE1 and a second pixel electrode PE2.

The substrate 100 has a display region 102 and a peripheral region 104. The display region 102 includes at least one pixel region U, and each pixel region U has a first sub-pixel region P1 and a second sub-pixel region P2.

The scan line SL is disposed on the substrate 100. In this embodiment, the scan line SL is located in the middle of the pixel region U. In other words, the scan line SL is located between the first sub-pixel region P1 and the second sub-pixel region P2.

The first data line set DLS1 is disposed on the substrate 100 and located at only one side of the pixel region U. Particularly, the first data line set DLS1 is located at the left side of the first sub-pixel region P1 and the left side of the second sub-pixel region P2. The intersection between the first data line set DLS1 and the scan line SL is the first intersecting region 202. The first data line set DLS1 includes the first data line DL1 and the second data line DL2 that are intersected to form the second intersecting regions 204 and 208. The first data line DL1 is electrically insulated from the second data line DL2.

In this embodiment, the first data line DL1 is a complete signal line, and the second data line DL2 includes a plurality of line segments 206a, 206b, 206c, 206d, and 206e. Specifically, the level of the line segments 206b and 206d of the second data line DL2 located in the second intersecting regions 204 and 208 is different from the level of the first data line DL1 located in the second intersecting regions 204 and 208. In this embodiment, the first data line DL1 and the line segments 206a, 206c, and 206e of the second data line DL2 are in the same film layer. The line segments 206b and 206d of the second data line DL2 are located above the first data line DL1 and cross over the first data line DL1. Here, the line segments 206b and 206d can be made of a metallic material or any other conductive material (such as an alloy, a metal nitride material, a metal oxide material, a metal oxynitride material, or any other suitable material), or a stacked layer containing the metallic material and any other conductive material. An insulating layer is sandwiched between the first data line DL1 and the line segments 206b and 206d of the second data line DL2, such that the first data line DL1 is electrically insulated from the second data line DL2. The line segments 206a, 206b, 206c, 206d, and 206e of the second data line DL2 can be electrically connected to one another directly or through contact windows.

The second data line set DLS2 is disposed on the substrate 100 and located at the other side of the pixel region U. Particularly, the second data line set DLS2 is located at the right side of the first sub-pixel region P1 and the right side of the second sub-pixel region P2. The intersection between the second data line set DLS2 and the scan line SL is the third intersecting region 212. The second data line set DLS2 includes the third data line DL3 and the fourth data line DL4 that are intersected to form the fourth intersecting regions 214 and 218. The third data line DL3 is electrically insulated from the fourth data line DL4.

In this embodiment, the third data line DL3 is a complete signal line, and the fourth data line DL4 includes a plurality of line segments 216a, 216b, 216c, 216d, and 216e. Specifically, the level of the line segments 216b and 216d of the fourth data line DL4 located in the fourth intersecting regions 214 and 218 is different from the level of the third data line DL3 located in the fourth intersecting regions 214 and 218. In this embodiment, the third data line DL3 and the line segments 216a, 216c, and 216e of the fourth data line DL4 are in the same film layer. The line segments 216b and 216d of the fourth data line DL4 are located above the third data line DL3 and cross over the third data line DL3. An insulating layer is also sandwiched between the third data line DL3 and the line segments 216b and 216d of the fourth data line DL4, such that the third data line DL3 is electrically insulated from the fourth data line DL4 The line segments 216a, 216b, 216c, 216d, and 216e of the fourth data line DL4 can be electrically connected to one another directly or through contact windows.

The first active device T1 is electrically connected to the scan line SL and electrically connected to the first data line DL1 or the second data line DL2 in the first data line set DLS1. In this embodiment, the first active device T1 is electrically connected to the first data line DL1, for instance. The second active device T2 is electrically connected to the scan line SL and electrically connected to the third data line DL3 or the fourth data line DL4 in the second data line set DLS2. In this embodiment, the second active device T2 is electrically connected to the fourth data line DL4, for instance. The first and the second active devices T1 and T2 are, for example, bottom-gate TFTs or top-gate TFTs, and each of the first and the second active devices T1 and T2 includes a gate, a source, and a drain. The gate of the first active device T1 is electrically connected to the scan line SL, and the source of the first active device T1 is electrically connected to the first data line DL1. The gate of the second active device T2 is electrically connected to the scan line SL, and the source of the second active device T2 is electrically connected to the fourth data line DL4.

The first pixel electrode PE1 is disposed in the first sub-pixel region P1 and electrically connected to the first active device T1. The second pixel electrode PE2 is disposed in the second sub-pixel region P2 and electrically connected to the second active device T2. The first and the second pixel electrodes PE1 and PE2 can be transparent pixel electrodes, reflective pixel electrodes, or transflective pixel electrodes. According to an embodiment of the invention, the first pixel electrode PE1 and the second pixel electrode PE2 are electrically connected to the drain of the first active device T1 and the drain of the second active device T2 through contact windows (not shown), respectively.

In this embodiment, the first data line DL1 and the second data line DL2 have different polarity. The third data line DL3 and the fourth data line DL4 have different polarity In detail, when the aforesaid pixel structure is operated or driven, signals on the first data line DL1 and on the second data line DL2 respectively have the negative polarity (−) and the positive polarity (+) within the same time period. Alternatively, the signals on the first data line DL1 and on the second data line DL2 respectively have the positive polarity (+) and the negative polarity (−) within the same time period. Signals on the third data line DL3 and on the fourth data line DL4 respectively have the negative polarity (−) and the positive polarity (+) within the same time period. Alternatively, the signals on the third data line DL3 and on the fourth data line DL4 respectively have the positive polarity (+) and the negative polarity (−) within the same time period. The polarity of the first data line DL1, the polarity of the second data line DL2, the polarity of the third data line DL3, and the polarity of the fourth data line DL4 are relative to the common voltage (Vcom) in the display panel.

In this embodiment, the first data line set DLS1 (the first and the second data lines DL1 and DL2) is disposed at one side of the pixel region U (the first and the second sub-pixel regions P1 and P2), and the second data line set DLS2 (the third and the fourth data lines DL3 and DL4) is disposed at the other side of the pixel region U (the first and the second sub-pixel regions P1 and P2). The first and the second data lines DL1 and DL2 have different polarity, and the third and the fourth data lines DL3 and DL4 have different polarity. Hence, even though the distance between the pixel electrodes PE1 and PE2 and the data line sets DLS1 and DLS2 located at respective sides of the pixel electrodes PE1 and PE2 is different because of process variation, the coupling capacitance between the pixel electrodes PE1 and PE2 and the data line sets DLS1 (the first and the second data lines DL1 and DL2) and DLS2 (the third and the fourth data lines DL3 and DL4) located at respective sides of the pixel electrodes PE1 and PE2 can be compensated, and thereby the vertical cross-talk phenomenon can be mitigated.

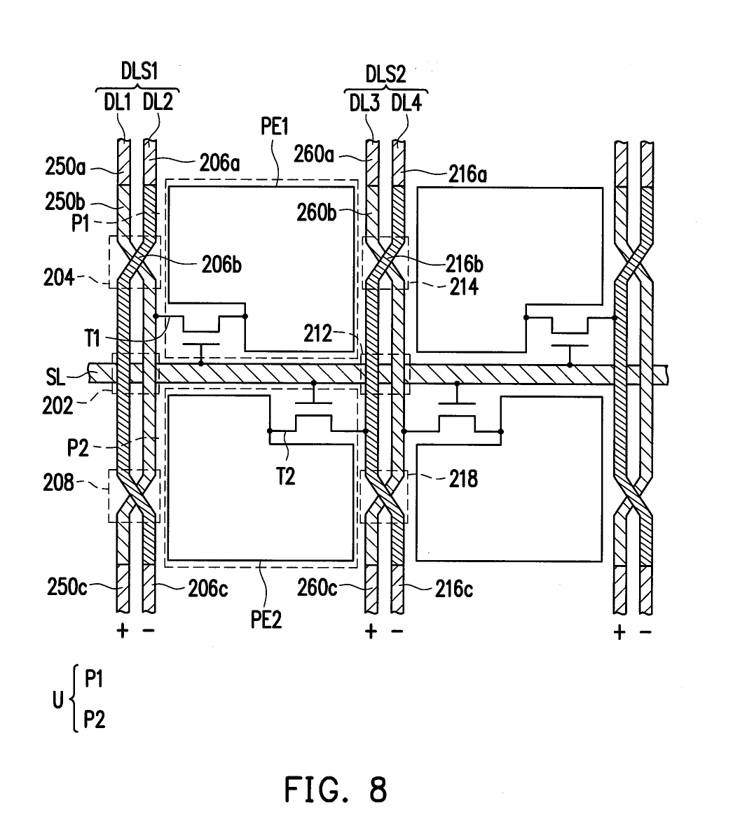

FIG. 8 is a schematic top view partially illustrating a pixel array according to an embodiment of the invention. The embodiment shown in FIG. 8 is similar to the embodiment shown in FIG. 7, and thus components identical to those in FIG. 7 are represented by the same numerals in FIG. 8 and are not repeated herein. The difference between the embodiment shown in FIG. 8 and the embodiment shown in FIG. 7 lies in that the first data line DL1 includes a plurality of line segments 250a, 250b, and 250c, and the second data line DL2 includes a plurality of line segments 206a, 206b, and 206c. The level of the line segment 206b of the second data line DL2 located in the intersecting region 204 is different from the level of the line segment 250b of the first data line DL1 located in the intersecting region 204. Specifically, the line segments 250a and 250c of the first data line DL1 and the line segments 206a and 206c of the second data line DL2 are in the same film layer/at the same level. The line segment 206b of the second data line DL2 is located above the line segment 250b of the first data line DL1 and crosses over the line segment 250b of the first data line DL1. Without doubt, in other embodiments of the invention, the line segment 206b of the second data line DL2 can be located below the line segment 250b of the first data line DL1 and across the line segment 250b of the first data line DL1. Similarly, the line segments 250a, 250b, and 250c of the first data line DL1 can be electrically connected to one another directly or through contact windows. The line segments 206a, 206b, and 206c of the second data line DL2 can be electrically connected to one another directly or through contact windows.

The third data line DL3 includes a plurality of line segments 260a, 260b, and 260c, and the fourth data line DL4 includes a plurality of line segments 216a, 216b, and 216c. The level of the line segment 216b of the fourth data line DL4 located in the intersecting region 214 is different from the level of the line segment 260b of the third data line DL3 located in the intersecting region 214. Specifically, the line segments 260a and 260c of the third data line DL3 and the line segments 216a and 216c of the fourth data line DL4 are in the same film layer/at the same level. The line segment 216b of the fourth data line DL4 is located above the line segment 260b of the third data line DL3 and crosses over the line segment 260b of the third data line DL3. Without doubt, in other embodiments of the invention, the line segment 216b of the fourth data line DL4 can be located below the line segment 260b of the third data line DL3 and across the line segment 260b of the third data line DL3. Similarly, the line segments 260a, 260b, and 260c of the third data line DL3 can be electrically connected to one another directly or through contact windows. The line segments 216a, 216b, and 216c of the fourth data line DL4 can be electrically connected to one another directly or through contact windows.

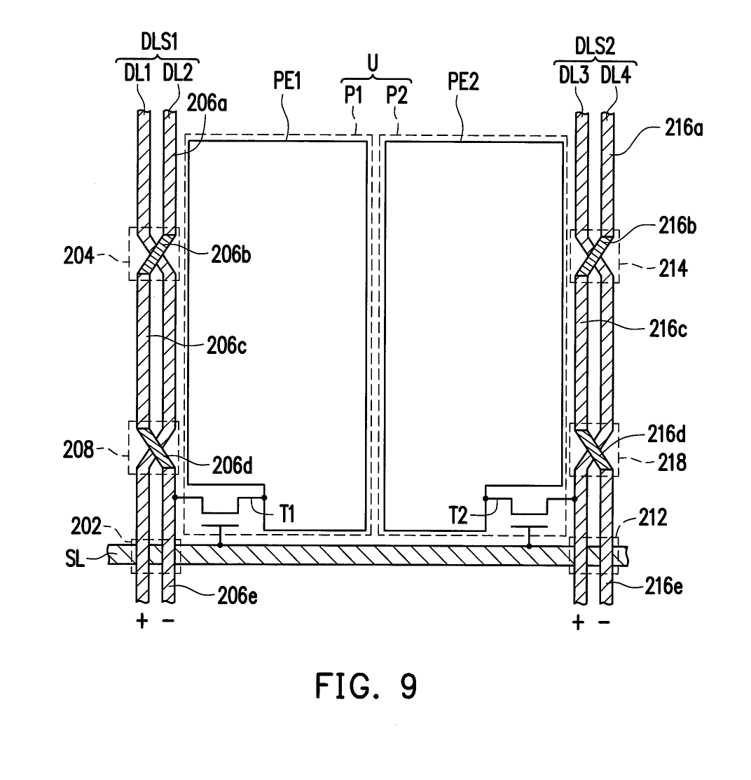

FIG. 9 is a schematic top view partially illustrating a pixel array according to an embodiment of the invention. The embodiment shown in FIG. 9 is similar to the embodiment shown in FIG. 7, and thus components identical to those in FIG. 7 are represented by the same numerals in FIG. 9 and are not repeated herein. The difference between the embodiment shown in FIG. 9 and the embodiment shown in FIG. 7 lies in that the scan line SL is located at one side of the pixel region U; namely, the scan line SL is located at one side of the first and the second sub-pixel regions P1 and P2. In FIG. 9, the scan line SL is located at the bottom of the first and the second sub-pixel regions P1 and P2, for instance. Space exists between the first sub-pixel region P1 and the second sub-pixel region P2. That is to say, there are no data lines or other conductive wires substantially parallel to the data lines located at between the first sub-pixel region P1 and the second sub-pixel region P2. Preferably, there are no data lines or other conductive wires substantially parallel to the data lines located below the space. In other embodiments of the invention, a common line or a floating electrode may be placed between the first sub-pixel region P1 and the second sub-pixel region P2 in order to increase capacitance or enhance light-shielding effects.

In the embodiment shown in FIG. 9, the first data line set DLS1 is disposed on the substrate 100 and located at one side of the pixel region U. The second data line set DLS2 is disposed on the substrate 100 and located at the other side of the pixel region U. In particular, the first data line set DLS1 is located at the left side of the first sub-pixel region P1. The second data line set DLS2 is located at the right side of the second sub-pixel region P2.

Besides, the intersection between the first data line set DLS1 and the scan line SL is the first intersecting region 202. The intersection between the second data line set DLS2 and the scan line SL is the third intersecting region 212. The first data line set DLS1 includes the first data line DL1 and the second data line DL2 that are intersected to form the second intersecting regions 204 and 208. The first data line DL1 is electrically insulated from the second data line DL2. The second data line set DLS2 includes the third data line DL3 and the fourth data line DL4 that are intersected to form the fourth intersecting regions 214 and 218. The third data line DL3 is electrically insulated from the fourth data line DL4. The first data line DL1 is a complete signal line, and the second data line DL2 includes a plurality of line segments 206a, 206b, 206c, 206d, and 206e. The level of the line segments 206b and 206d of the second data line DL2 located in the second intersecting regions 204 and 208 is different from the level of the first data line DL1 located in the second intersecting regions 204 and 208. The third data line DL3 is a complete signal line, and the fourth data line DL4 includes a plurality of line segments 216a, 216b, 216c, 216d, and 216e. The level of the line segments 216b and 216d of the fourth data line DL4 located in the fourth intersecting regions 214 and 218 is different from the level of the third data line DL3 located in the fourth intersecting regions 214 and 218.

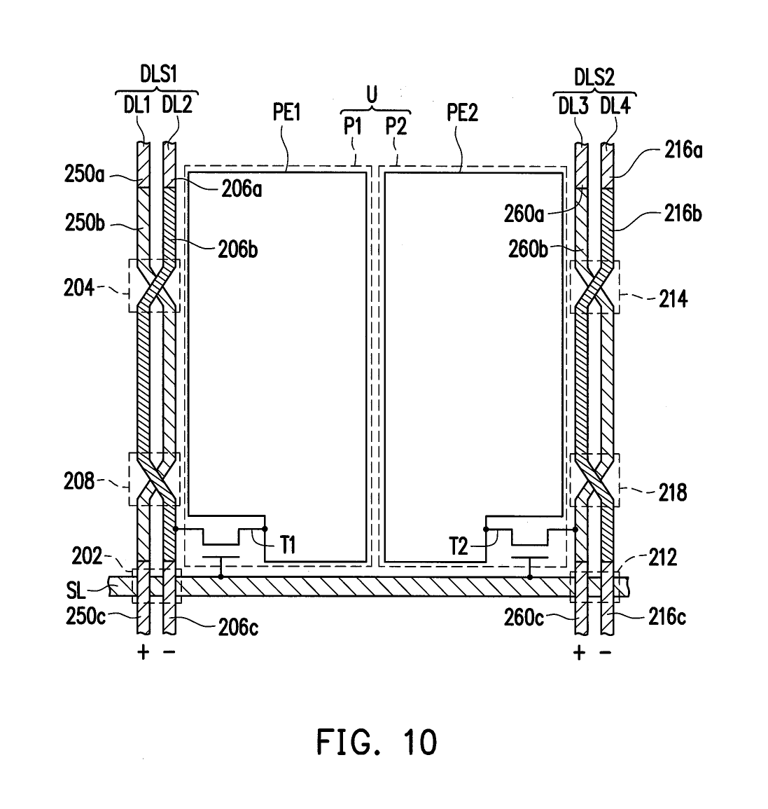

FIG. 10 is a schematic top view partially illustrating a pixel array according to an embodiment of the invention. The embodiment shown in FIG. 10 is similar to the embodiment shown in FIG. 9, and thus components identical to those in FIG. 9 are represented by the same numerals in FIG. 10 and are not repeated herein. The difference between the embodiment shown in FIG. 10 and the embodiment shown in FIG. 9 lies in that the first data line DL1 includes a plurality of line segments 250a, 250b, and 250c, and the second data line DL2 includes a plurality of line segments 206a, 206b, and 206c. The level of the line segment 206b of the second data line DL2 located in the intersecting region 204 is different from the level of the line segment 250b of the first data line DL1 located in the intersecting region 204. The third data line DL3 includes a plurality of line segments 260a, 260b, and 260c, and the fourth data line DL4 includes a plurality of line segments 216a, 216b, and 216c. The level of the line segment 216b of the fourth data line DL4 located in the intersecting region 214 is different from the level of the line segment 260b of the third data line DL3 located in the intersecting region 214.

The embodiments of the invention described above can be cross-referenced and applied to various display panels, such as an LCD panel, an organic light emitting display panel, a flexible display panel, electronic paper, any other appropriate display panel, or a combination thereof.

In light of the foregoing, the data line set is located at one side of the sub-pixel region, and the data line set includes two intersecting data lines in this invention. When the two data lines are provided with the signals having different polarity, the data lines having two different polarity are located at only one side of the pixel electrode. Therefore, even though the distance between each pixel electrode and the data lines located at respective sides of the pixel electrode is different because of process variation, the coupling capacitance between each pixel electrode and the data lines located at the same side of the pixel electrode can be compensated, and thereby the vertical cross-talk phenomenon can be mitigated.

Moreover, in another embodiment of the invention, each of the two data line sets is respectively disposed at one side of the sub-pixel region, and each of the two data line sets includes two intersecting data lines. When the two data lines in each data line set are provided with the signals having different polarity, the data lines having two different polarity are located at respective sides of the pixel electrode. Therefore, even though the distance between each pixel electrode and the data lines located at respective sides of the pixel electrode is different because of process variation, the coupling capacitance between each pixel electrode and the data lines located at the respective sides of the pixel electrode can be compensated, and thereby the vertical cross-talk phenomenon can be mitigated.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A pixel structure comprising:
a substrate having a display region and a peripheral region, wherein the display region includes at least one sub-pixel region;
a scan line disposed on the substrate;
a data line set disposed on the substrate, located at one side of the at least one sub-pixel region, and intersected with the scan line to form at least one first intersecting region, wherein the data line set comprising a first data line and a second data line, the first data line and the second data line being intersected without being overlapped completely to form at least one second intersecting region located in the display region, the first data line and the second data line are separated from and not connected to each other;
an active device electrically connected to the scan line and electrically connected to the first data line or the second data line in the data line set, the active device comprises a gate, a source, and a drain; and
a pixel electrode disposed in the at least one sub-pixel region and electrically connected to the active device, wherein the pixel electrode receives a signal from the first data line or the second data line to which the active device is connected during the active device is turn on,
wherein the at least one second intersecting region neither exists in a connection portion defined by the portion where the source of the active device and the second data line are connected nor exists in another connection portion defined by the portion where the source of an another active device and the first data line are connected.

2. The pixel structure of claim 1, wherein the first data line and the second data line have different polarity.

3. The pixel structure of claim 1, wherein the first data line is a complete signal line, the second data line comprises a plurality of line segments, and a level of one of the line segments of the second data line located in the at least one second intersecting region is different from a level of the first data line located in the at least one second intersecting region, and the first data line located in the at least one first intersecting region and one of the segments of the second data line located in the at least one first intersecting region are in the same film layer.

4. The pixel structure of claim 1, wherein the first data line comprises a plurality of first line segments, the second data line comprises a plurality of second line segments, and a level of one of the second line segments of the second data line located in the at least one second intersecting region is different from a level of one of the first line segments of the first data line located in the at least one second intersecting region.

5. The pixel structure of claim 1, further comprising another data line set disposed on the substrate, the another data line set being located at the other side of the at least one sub-pixel region and intersected with the scan line to form at least one third intersecting region, the another data line set comprising a third data line and a fourth data line, the third data line and the fourth data line being intersected to form at least one fourth intersecting region, the third data line being insulated from the fourth data line.

6. The pixel structure of claim 5, wherein the third data line and the fourth data line in the another data line set have different polarity.

7. The pixel structure of claim 5, wherein the third data line is a complete signal line, the fourth data line comprises a plurality of line segments, and a level of one of the line segments of the fourth data line located in the at least one fourth intersecting region is different from a level of the third data line located in the at least one fourth intersecting region, and the third data line located in the at least one third intersecting region and one of the segments of the fourth data line located in the at least one third intersecting region are in the same film layer.

8. The pixel structure of claim 5, wherein the third data line comprises a plurality of first line segments, the fourth data line comprises a plurality of second line segments, and a level of one of the second line segments of the fourth data line located in the at least one fourth intersecting region is different from a level of one of the first line segments of the third data line located in the at least one fourth intersecting region.

9. The pixel structure of claim 1, wherein the at least one second intersecting region is located in a middle region at one side of the at least one sub-pixel region.

10. A pixel structure comprising:
a substrate having a display region and a peripheral region, wherein the display region includes a plurality of sub-pixel regions;
a scan line disposed on the substrate;
a data line set disposed on the substrate, located at one side of one sub-pixel region, and intersected with the scan line to form at least one first intersecting region, wherein the data line set comprising a first data line and a second data line, the first data line and the second data line being intersected without being overlapped completely to form at least one second intersecting region located in the display region, the first data line and the second data line are separated from and not connected to each other, the first data line has a first polarity while the second data line has a second polarity, wherein the first polarity is different form the second polarity;
another data line set disposed on the substrate, the another data line set being located at the other side of the one sub-pixel region and intersected with the scan line to form at least one third intersecting region, the another data line set is located between the one sub-pixel region and another sub-pixel region adjacent to the one sub-pixel region, the another data line set comprising a third data line and a fourth data line, the third data line and the fourth data line being intersected to form at least one fourth intersecting region, the third data line and the fourth data line are separated from and not connected to each other, the third data line has the first polarity while the fourth data line has the second polarity;
yet another data line set disposed on the substrate, the yet another data line set being located at the other side of the another sub-pixel region and intersected with the scan line to form at least one fifth interesting region, the yet another data line set comprising a fifth data line and a sixth data line, the fifth data line and the sixth data line being intersected to form at least one sixth intersecting region, the fifth data line and the sixth data line are separated from and not connected to each other, the fifth data line has the first polarity while the sixth data line has the second polarity;
an active device of the one sub-pixel region electrically connected to the scan line and electrically connected to the second data line, but not connected to the first data line;
another active device of the another sub-pixel region electrically connected to the scan line and electrically connected to the fourth data line, but not connected to the third data line;
a pixel electrode disposed in the one sub-pixel region and electrically connected to the active device, wherein the pixel electrode receives a signal from the second data line to which the active device is connected during the active device is turn on; and
another pixel electrode disposed in the another sub-pixel region and electrically connected to the another active device, wherein the another pixel electrode receives a signal from the fourth data line to which the active device is connected during the another active device is turn on.

11. The pixel structure of claim 10, wherein the at least one second intersecting region is located in a middle region at one side of the one sub-pixel region.

12. The pixel structure of claim 10, wherein the at least one fourth intersecting region is located in a middle region at the other side of the one sub-pixel region.

13. The pixel structure of claim 12, wherein the at least one fourth intersecting region is located in a middle region at the one side of the another sub-pixel region.

14. The pixel structure of claim 10, wherein the at least one sixth intersecting region is located in a middle region at the other side of the another sub-pixel region.
